(19) United States
(12) Patent Application Publication
(10) Pub. No.: US 2016/0197703 A1
(43) Pub. Date: Jul. 7, 2016

(54) LDPC-RS TWO-DIMENSIONAL CODE FOR GROUND WAVE CLOUD BROADCASTING

(71) Applicant: ELECTRONICS AND TELECOMMUNICATIONS RESEARCH INSTITUTE, Daejeon (KR)

(72) Inventors: Sung IK PARK, Daejeon (KR); Sun Hyoung KWON, Daejeon (KR); Heung Mook KIM, Daejeon (KR); Nam Ho HUR, Daejeon (KR)

(21) Appl. No.: 14/908,365

(22) PCT Filed: Aug. 11, 2014
(86) PCT No.: PCT/KR2014/007443

§ 371 Date: Jan. 28, 2016

(30) Foreign Application Priority Data
Sep. 10, 2013 (KR) 10-2013-0108314
Oct. 31, 2013 (KR) 10-2013-0130740
Aug. 8, 2014 (KR) 10-2014-0102102

(51) Int. Cl. H04L 1/00; H03M 13/15; H03M 13/29; H03M 13/11

(52) U.S. Cl. CPC H04L 1/0064; H04L 1/0041; H03M 13/1102; H03M 13/1515; H03M 13/2906

(57) ABSTRACT

A method of transmitting a terrestrial cloud transmission signal using a low density parity check (LDPC)-Reed Solomon (RS) two-dimensional code and a method and apparatus for adaptively decoding the LDPC-RS two-dimensional code are disclosed here. The method of transmitting a terrestrial cloud transmission signal includes encoding information to be transmitted into a two-dimensional code including an LDPC code and an RS code, and outputting encoded information, which is encoded into the two-dimensional code, row by row.

### TECHNICAL FIELD

Embodiments of the present invention relate to a two-dimensional code including a low density parity check (LDPC) code and a Reed-Solomon (RS) code in order to correct an error occurring over a wireless channel in a terrestrial cloud transmission system that operates over a single frequency network.

### BACKGROUND ART

Current terrestrial television (TV) broadcasting generates co-channel interference across an area within a distance that is three times a service radius, and thus the same frequency cannot be reused in the area within the distance that is three times the service radius. An area in which the same frequency cannot be reused is called a white space. Spectrum efficiency significantly deteriorates due to the occurrence of a white space. Accordingly, there arises a need for the development of a transmission technology capable of facilitating the elimination of a white space and the reuse of a frequency with an emphasis on an increase in transmission capacity and reception robustness in order to improve spectrum efficiency.

In response to this, the paper “Cloud Transmission: A New Spectrum-Reuse Friendly Digital Terrestrial Broadcasting Transmission System” published on September of 2012 in IEEE Transactions on Broadcasting, Vol. 58, No. 3 proposes a terrestrial cloud transmission technology that facilitates reuse of a frequency, does not generate a white space, and makes the construction and operation of a single frequency network easy.

Using this terrestrial cloud transmission technology, a broadcasting station can transmit the same nationwide content or locally different content over a single broadcasting channel. However, for this purpose, a receiver should receive one or more terrestrial cloud broadcast signals in an area in which signals transmitted from different transmitters overlap each other, that is, an overlap area, over a single frequency network, and then should distinguish and demodulate the received terrestrial cloud broadcast signals. That is, the receiver should demodulate one or more cloud broadcast signals in a situation in which co-channel interference is present and the timing and frequency synchronization between transmitted signals are not guaranteed. For this purpose, a terrestrial cloud transmission system should operate in an environment in which the power of a noise is larger than the power of a signal, that is, a negative Signal-to-Noise Ratio (SNR) environment.

Furthermore, the terrestrial cloud transmission system is generally designed in preparation for the worst case in order to provide a high-quality service to all viewers. That is, the terrestrial cloud transmission system is designed such that a viewer can reliably receive a terrestrial broadcast signal in the periphery of a broadcasting service zone (an area corresponding to the edge or boundary of the broadcasting service zone). This means that most of the broadcasting service zone has a considerably higher SNR than the periphery. For example, it is known that 80% or more of the broadcasting service zone has an SNR that is 5 dB or higher than that in the periphery. Accordingly, the terrestrial cloud transmission system should be able to decode information with lower latency and complexity in a high-SNR area than in a low-SNR area.

### DISCLOSURE

### Technical Problem

At least one embodiment of the present invention is directed to the provision of an LDPC-RS two-dimensional code that can operate in a negative SNR environment and also enables information to be decoded with minimum latency and complexity in a high-SNR environment.

At least one embodiment of the present invention is directed to the provision of a method and apparatus for adaptively decoding the LDPC-RS two-dimensional code.

### Technical Solution

In accordance with another aspect of the present invention, there is provided a method of transmitting a terrestrial cloud transmission signal, including encoding information to be transmitted into a two-dimensional code including a low density parity check (LDPC) code and a Reed Solomon (RS) code; and outputting encoded information, which is encoded into the two-dimensional code, row by row.

The two-dimensional code may be a code whose rows correspond to the RS code and whose columns correspond to the LDPC code.

The LDPC code may be an LDPC code having a Quasi-Cyclic (QC) structure.

The LDPC code may include matrix A having a size of g×K, a matrix B having a size of g×g, matrix C having a size of (N−K−g)×(K+g), matrix D having a size of (N−K−g)×(N−K−g), and matrix Z having a size of g×(N−K−g); and N may be the length of a codeword, K is the length of information, and g is a value varying depending on a code rate.

Encoding the information may include primarily encoding the information to be transmitted using the RS code row by row and secondarily encoding the information using the LDPC code column by column.

The method may further include, after encoding the information, dividing the encoded information which is encoded into the two-dimensional code into a plurality of blocks based on the size of a cyclic permutation matrix (CPM) constituting the LDPC code.

Outputting the encoded information may include outputting divided information, which is divided into the plurality of blocks, in a unit of a block.

Outputting the encoded information may include outputting divided information, which is divided into the plurality of blocks, in a unit of a bit.

The encoded information which is encoded into the two-dimensional code may be restored by partial decoding using information and partial parity constituting an LDPC codeword if the SNR of a received signal is equal to or higher than a first threshold.

The encoded information which is encoded into the two-dimensional code may be restored only by RS decoding without LDPC decoding if the SNR of a received signal is equal to or higher than a second threshold.

In accordance with another aspect of the present invention, there is provided a transmission apparatus for transmitting a terrestrial cloud transmission signal, including an encoding unit configured to encode information to be transmitted into a two-dimensional code including an LDPC code and an RS code; and an output unit configured to output encoded information, which is encoded into the two-dimensional code, row by row.

In accordance with another aspect of the present invention, there is provided a reception apparatus for receiving an LDPC-RS two-dimensional code, including an estimation unit configured to estimate the SNR of a received signal; a determination unit configured to determine a decoding algorithm to be applied to a codeword, encoded in a two-dimensional code including a low density parity check (LDPC) code and a Reed Solomon (RS) code, based on the estimated SNR; and a decoding unit configured to decode the codeword using the determined decoding algorithm.

The two-dimensional code may be a code whose rows correspond to the RS code and whose columns correspond to the LDPC code or a code whose rows correspond to the LDPC code and whose columns correspond to the RS code.

The LDPC code may be an LDPC code having a Quasi-Cyclic (QC) structure.

Part of the parity of the LDPC code may include an identity matrix.

The codeword may be a codeword that has been primarily encoded using the RS code row by row and secondarily encoded using the LDPC code column by column.

The estimation unit may estimate the SNR using any one of a preamble signal, a pilot signal and a training signal.

The determination unit may determine at least one of an LDPC decoding algorithm and an RS decoding algorithm to be the decoding algorithm to be applied to the codeword.

If it is determined that the LDPC decoding algorithm will be applied to the codeword, the determination unit may determine any one of an LDPC decoding algorithm using the whole codeword and an LDPC decoding algorithm using part of the codeword to be the LDPC decoding algorithm to be applied to the codeword.

In accordance with still another aspect of the present invention, there is provided a method of decoding a codeword encoded in a two-dimensional code including an LDPC code and an RS code, including estimating the SNR of a received signal; determining a decoding algorithm to be applied to a codeword based on the estimated SNR; and decoding the codeword using the determined decoding algorithm.

In accordance with still another aspect of the present invention, there is provided a decoding device, including a determination unit configured to determine a decoding algorithm to be applied to a codeword, encoded in a two-dimensional code including an LDPC code and an RS code, based on the estimated SNR of a received signal; and a decoding unit configured to decode the codeword using the determined decoding algorithm.

### Advantageous Effects

At least one embodiment of the present invention has the advantage of being able to decode information even in a negative SNR environment and also successfully decode information using only partial parity in a high-SNR environment because a two-dimensional code including an LDPC code and an RS code is employed.

At least one embodiment of the present invention has the advantage of decoding information in a high-SNR environment with minimum complexity and latency because a decoding algorithm having varying complexity and latency is adaptively employed based on SNR.

### DESCRIPTION OF DRAWINGS

FIG. 1 is a diagram illustrating the parity check matrix of a QC-LDPC code applied to at least an embodiment of the present invention;

FIG. 2 is a diagram illustrating the structure of an LDPC-RS two-dimensional code according to an embodiment of the present invention;

FIG. 3 is a diagram illustrating a process of encoding information using an LDPC-RS two-dimensional code according to an embodiment of the present invention;

FIG. 4 is a graph illustrating the BER performance of an LDPC-RS two-dimensional code in an additive white Gaussian noise (AWGN) channel according to an embodiment of the present invention;

FIG. 5 is a graph illustrating the BER performance of an LDPC-RS two-dimensional code in a fading channel according to an embodiment of the present invention;

FIG. 6 is a diagram illustrating an LDPC-RS two-dimensional code in a form where information for RS encoding is arranged in a row direction;

FIG. 7 is a diagram illustrating an LDPC-RS two-dimensional code in a form where information for RS encoding is arranged in a column direction;

FIG. 8 is a diagram illustrating that the LDPC-RS two-dimensional codes of FIGS. 6 and 7 are of the same type from a two-dimensional code viewpoint;

FIG. 9 is a diagram illustrating the partial decoding of an LDPC-RS two-dimensional code according to an embodiment of the present invention;

FIG. 10 is a graph illustrating performance based on the complexity and latency of an LDPC-RS two-dimensional code applied to an embodiment of the present invention;

FIGS. 11 and 12 are diagrams illustrating information transmission methods using an LDPC-RS two-dimensional code according to embodiments of the present invention;

FIG. 13 is a flowchart illustrating a method of transmitting a terrestrial cloud transmission signal according to an embodiment of the present invention;

FIG. 14 is a flowchart illustrating a method of adaptively encoding an LDPC-RS two-dimensional code according to an embodiment of the present invention;

FIG. 15 is a diagram illustrating a case where only RS decoding is performed on an LDPC-RS two-dimensional code applied to an embodiment of the present invention;

FIG. 16 is a block diagram illustrating a transmission apparatus for transmitting a codeword encoded in an LDPC-RS two-dimensional code according to an embodiment of the present invention; and

FIG. 17 is a block diagram illustrating a reception apparatus for receiving a codeword encoded in an LDPC-RS two-dimensional code according an embodiment of the present invention.

### MODE FOR INVENTION

Embodiments of the present invention are described with reference to the accompanying drawings in order to describe the present invention in detail so that those having ordinary knowledge in the technical field to which the present invention pertains can easily practice the present invention. However, the present invention may be implemented in various different forms, and are not limited to the embodiments described herein. Portions unrelated to the description are omitted in the drawings in order to clearly describe the present invention, and like reference numerals are assigned to like components throughout the drawings.

Throughout the specification, when any part is described as “comprising” or “including” any component, this means that the part does not exclude any other component but includes any other component unless described otherwise. The terms “˜unit” described herein refers to a unit configured to process at least one function or operation, and the “˜unit” may be implemented by hardware, software, or a combination of hardware and the software.

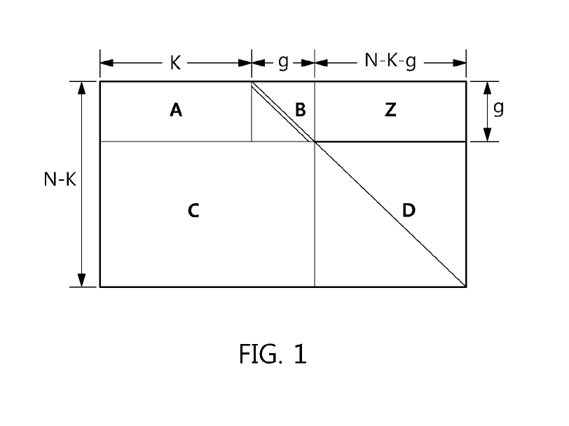

FIG. 1 is a diagram illustrating the parity check matrix of a QC-LDPC code applied to at least an embodiment of the present invention.

An LDPC code is known as an error correction code closest to the Shannon limit for an AWGN channel, and has the advantages of providing asymptotically excellent performance and enabling parallelizable decoding, compared to a turbo code. Generally, an LDPC code is defined by a low-density parity check matrix (PCM) that is randomly generated. However, a randomly generated LDPC code requires a large amount of memory to store a PCM, and requires a large amount of time to access memory.

In order to overcome these problems, a QC-LDPC code that is an LDPC code having a QC structure may be used. A QC-LDPC code includes zero matrices or circulant permutation matrices (CPMs), and is defined by a PCM H that is given by the following Equation 1:

$$H = [ \begin{matrix}{P}^{{a}_{11}} & {P}^{{a}_{12}} & … & {P}^{{a}_{1 n}} \\ {P}^{{a}_{21}} & {P}^{{a}_{22}} & … & {P}^{{a}_{2 n}} \\ ⋮ & ⋮ & ⋱ & ⋮ \\ {P}^{{a}_{m 1}} & {P}^{{a}_{m 2}} & … & {P}^{{a}_{mn}}\end{matrix} ] , for {a}_{ij} ∈ \{ 0 , 1 , … , L - 1 , ∞ \} \qquad ( 1 )$$

In Equation 1, P is a CPM having a size of L×L, and is given as the following Equation 2:

$${P}_{L \times L} = [ \begin{matrix}0 & 1 & 0 & … & 0 \\ 0 & 0 & 1 & … & 0 \\ ⋮ & ⋮ & ⋮ & ⋱ & ⋮ \\ 0 & 0 & 0 & … & 1 \\ 1 & 0 & 0 & … & 0\end{matrix} ] \qquad ( 2 )$$

In Equation 2, Pⁱ is obtained by shifting an identity matrix I (=)P⁰ having a size of L×L to the right i (0<L) times, and P^{∞} is a zero matrix having a size of L×L. Accordingly, in the case of a QC-LDPC code, it is sufficient if only index exponent i is stored in order to store Pⁱ, and thus the amount of memory required to store a PCM is considerably reduced.

Accordingly, the QC-LDPC code defined by a PCM, as illustrated in FIG. 1, may be applied to at least one embodiment of the present invention. In FIG. 1, N is the length of a codeword, K is the length of information, and g is a value varying depending on the code rate. Matrices A and C have sizes of (g×K) and (N−K−g)×(K+g), respectively, and are composed of a zero matrix having a size of L×L and a cyclic permutation matrix having a size of L×L. Matrix Z is a zero matrix having a size of (g×(N−K−g), and matrix D is an identity matrix having a size of (N−K−g)×(N−K−g). Matrix B is a dual diagonal matrix having a size of g×g, and is given as the following Equation 3:

$${B}_{g \times g} = [ \begin{matrix}{I}_{L \times L} & 0 & 0 & … & 0 & 0 & 0 \\ {I}_{L \times L} & {I}_{L \times L} & 0 & … & 0 & 0 & 0 \\ 0 & {I}_{L \times L} & {I}_{L \times L} & ⋮ & 0 & 0 & 0 \\ ⋮ & ⋮ & ⋮ & ⋱ & ⋮ & ⋮ & ⋮ \\ 0 & 0 & 0 & … & {I}_{L \times L} & {I}_{L \times L} & 0 \\ 0 & 0 & 0 & … & 0 & {I}_{L \times L} & {I}_{L \times L}\end{matrix} ] \qquad ( 3 )$$

In Equation 3, I_{L×L} is an identity matrix having a size of L×L. In the dual diagonal matrix B, element matrices that constitute a dual diagonal line are identity matrices and the remaining element matrices are zero matrices, as shown in Equation 3. The element matrices that constitute the dual diagonal line of the dual diagonal matrix B and the element matrices that constitute the diagonal line of the identity matrix D may be successive with each other.

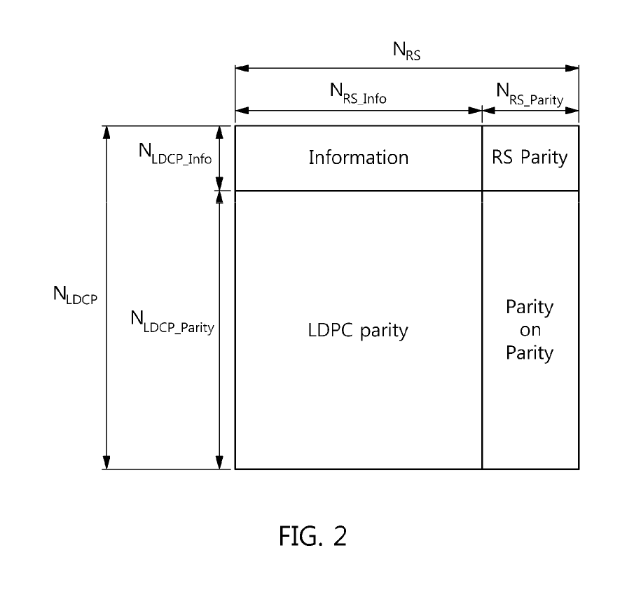

The QC-LDPC code illustrated in FIG. 1 exhibits very excellent performance closest to the Shannon limit. Furthermore, since part of parity (a portion corresponding to the matrix D) is composed of an identity matrix, conversion from a mother code having a low code rate to a code having a high code rate may be easily performed via a puncturing or truncating technique. In other words, the QC-LDPC code has a rate-compatible characteristic, like a raptor code, due to a PCM having a special structure, such as that illustrated in FIG. 1. However, the QC-LDPC code experiences an error floor phenomenon in a region where the bit error rate (BER) is 10⁻⁸. Furthermore, since a burst error occurs over a fading channel, a complicated bit and frequency interleaver should be used in order to ensure performance over the fading channel. Accordingly, in an embodiment of the present invention, information may be encoded using an LDPC-RS two-dimensional code, such as that illustrated in FIG. 2.

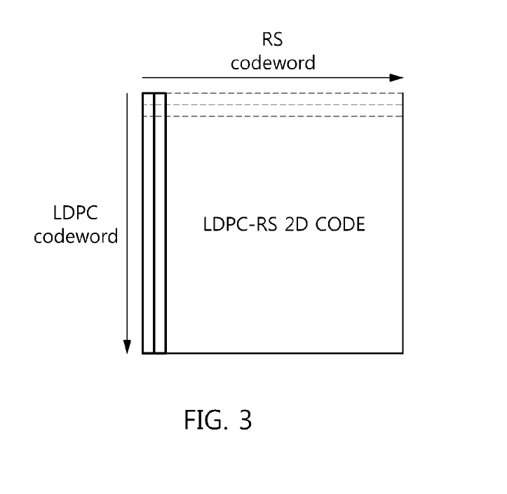

FIG. 2 is a diagram illustrating the structure of an LDPC-RS two-dimensional code according to an embodiment of the present invention, and FIG. 3 is a diagram illustrating a process of encoding information using an LDPC-RS two-dimensional code according to an embodiment of the present invention.

In FIG. 2, N_{RS}_{_}_{Info}, N_{RS}_{_}_{Parity} and N_{RS} denote the lengths of information, parity and a codeword for an RS code, respectively, and N_{LDPC}_{_}_{Info}, N_{LDPC}_{_}_{Parity} and N_{LDPC} denote the lengths of information, parity and a codeword for an LDPC code, respectively. As illustrated in FIG. 2, the rows of an LDPC-RS two-dimensional code according to an embodiment of the present invention correspond to an RS code, and the columns thereof correspond to an LDPC code. In this case, the LDPC code corresponding to the columns of the LDPC-RS two-dimensional code may be configured in the same structure, that is, in the form of the same PCM, as the QC-LDPC code illustrated in FIG. 1.

Accordingly, a transmission apparatus for terrestrial cloud transmission according to an embodiment of the present invention may primarily encode information to be transmitted using an RS code row by row, may secondarily encode the information using an LDPC code column by column, and then may output a result, as illustrated in FIG. 3. A reception apparatus that has received the information (codewords) encoded into the LDPC-RS two-dimensional code may primarily decode LDPC codewords, and may secondarily decode RS codewords.

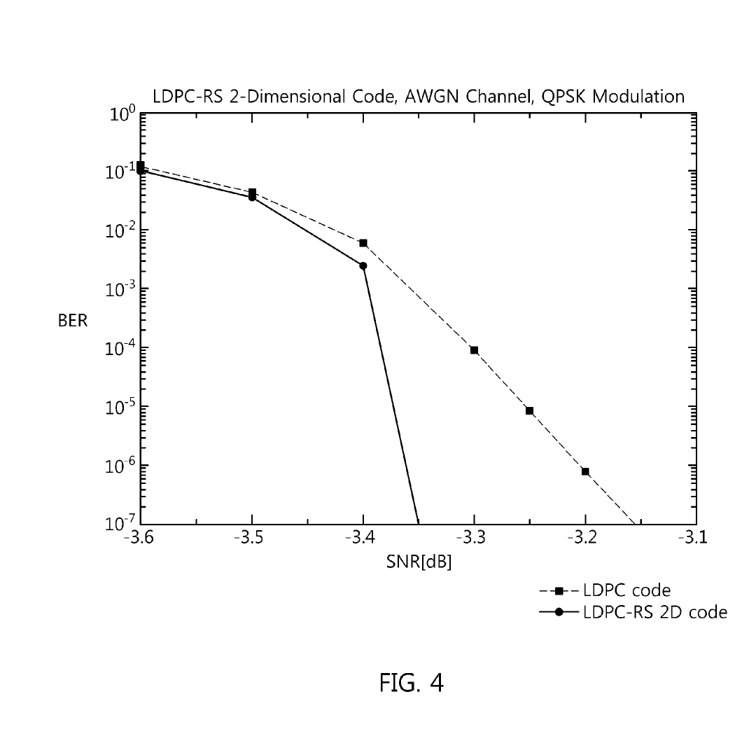

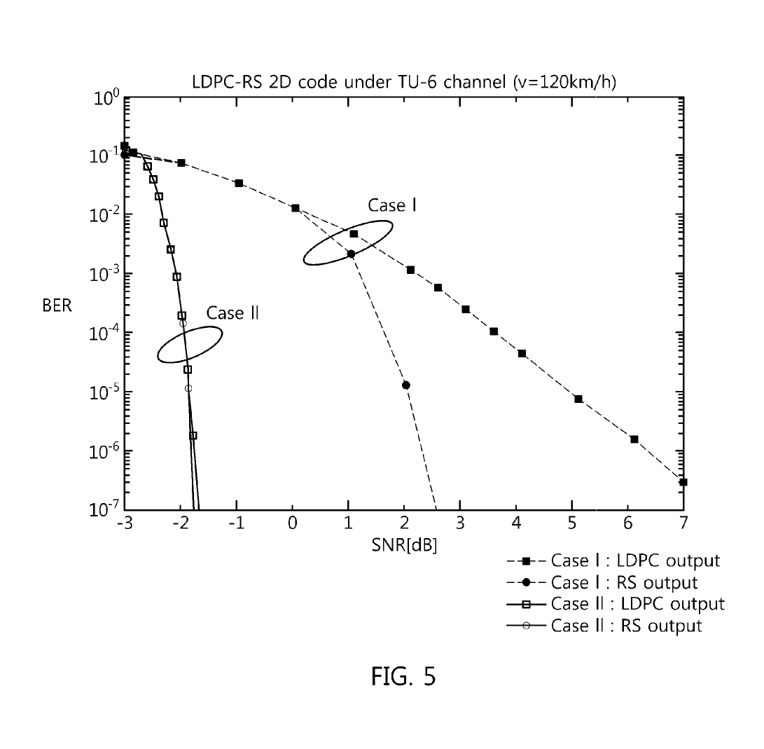

FIG. 4 is a graph illustrating the BER performance of an LDPC-RS two-dimensional code in an AWGN channel according to an embodiment of the present invention, and FIG. 5 is a graph illustrating the BER performance of an LDPC-RS two-dimensional code in a fading channel according to an embodiment of the present invention.

In FIG. 4, by way of example, the BER performance of an LDPC code having a length of 16200 or 64800 bits and a code rate of 1/4 in an AWGN channel and the BER performance of an LDPC-RS two-dimensional code, composed of a shortened RS code having a length of 160 bytes and being capable of correcting a seven or less-byte error and the LDPC code, in the AWGN channel. Quadratic phase shift keying (QPSK) is used as a modulation method, and a log-likelihood ratio (LLR)-based sum-product algorithm that performs 50 repetitions of decoding is used for the decoding of an LDPC codeword. For the decoding of an RS codeword, a hard-decision Berlekamp-Massey algorithm that is generally and widely employed is used.

Referring to FIG. 4, it can be seen that in the AWGN channel, the RS output of the LDPC-RS two-dimensional code (an output obtained by decoding the RS codeword after decoding the LDPC codeword) exhibits performance superior to the output of an existing LDPC code and eliminates an error floor phenomenon that occurs in the LDPC code. Furthermore, it can be seen that the BER performance of the LDPC-RS two-dimensional code exhibits a sharper slope than that of the LDPC code.

Meanwhile, the LDPC-RS two-dimensional codeword according to an embodiment of the present invention may be output column by column or row by row, as shown in the following Table 1:

TABLE 1

| Output of 2D code | Effect |
|---|---|
| case I (column-by-column) | no interleaving |
| output in order of LDPC codeword | |
| case II (row-by-row) | time & frequency interleaving |
| output in order of RS codeword | |

Referring to Table 1, case I, that is, an column-by-column output (an output in order of the LDPC codeword), does not have any interleaving effect, whereas case □, that is, a row-by-row output (an output in order of the RS codeword), has a time & frequency interleaving effect attributable to a block interleaver. Accordingly, the cases I and II have no performance difference in an AWGN channel, but exhibit a considerable performance difference in a fading channel, as illustrated in FIG. 5.

In FIG. 5, an LDPC output exhibits performance when only an LDPC codeword is decoded, whereas an RS output exhibits performance when both an LDPC codeword and an RS codeword are decoded. The LDPC and RS codes used in FIG. 5 are the same as those of FIG. 4, the length of the LDPC code is fixed to 64800 bits, and the error correction capability of the RS code is fixed to 7 bytes. Furthermore, a Typical Urban (TU)-6 channel having a speed of 120 km/h has been contemplated for fading.

As illustrated in FIG. 5, in the fading channel, the case □ exhibits very excellent performance compared to the case I. The reason for this is the case I (a column-by-column output) cannot appropriately distribute burst errors that occur in the fading channel in quantity while the case II (a row-by-row output) can appropriately distribute burst errors via a block interleaver having a time and frequency interleaving effect. Accordingly, in order to effectively distribute burst errors occurring in the fading panel, an LDPC-RS two-dimensional codeword according to an embodiment of the present invention may be output row by row.

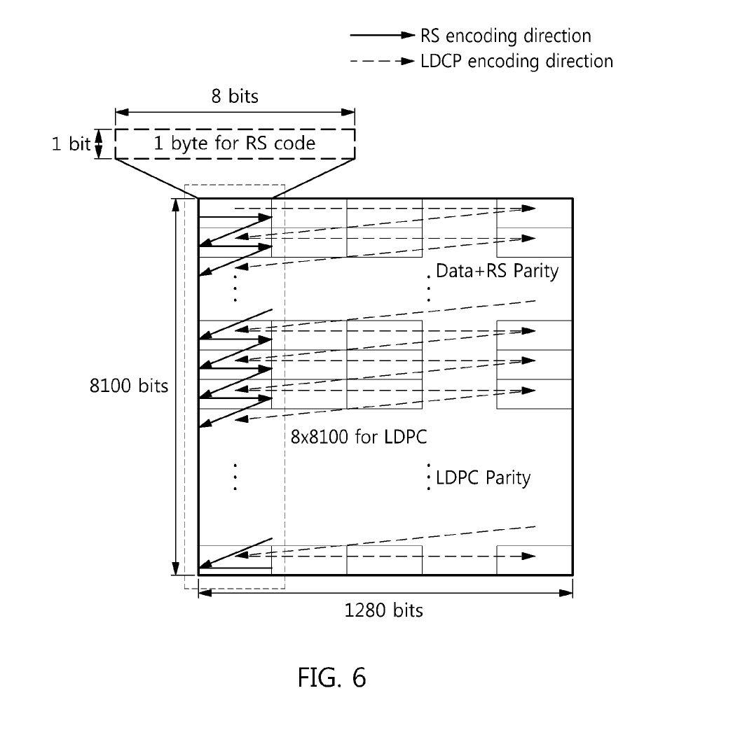

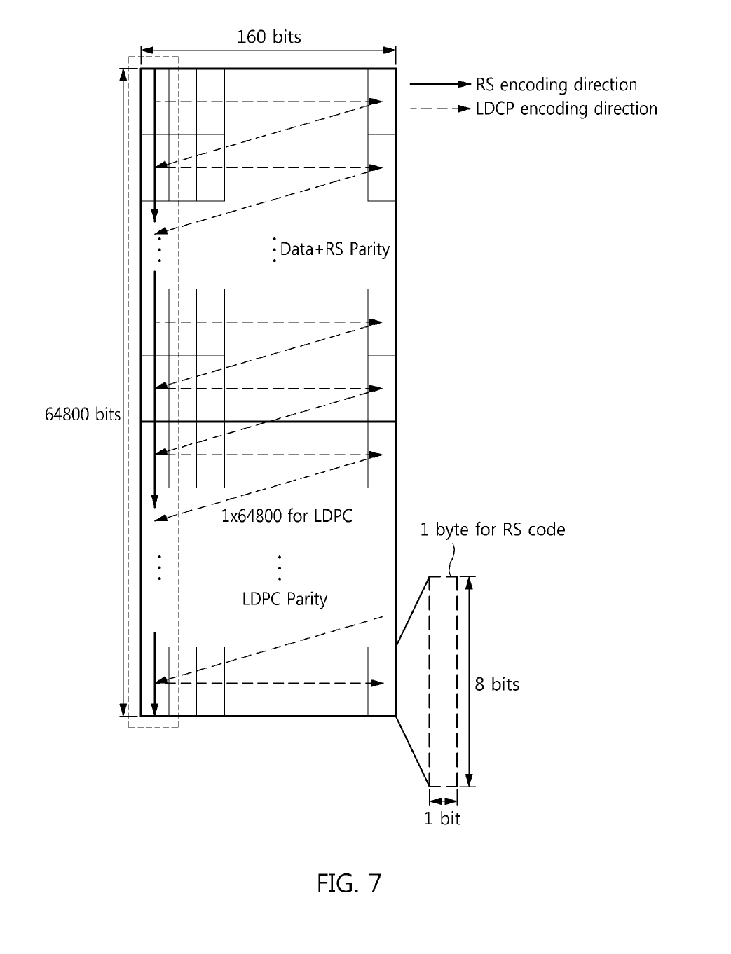

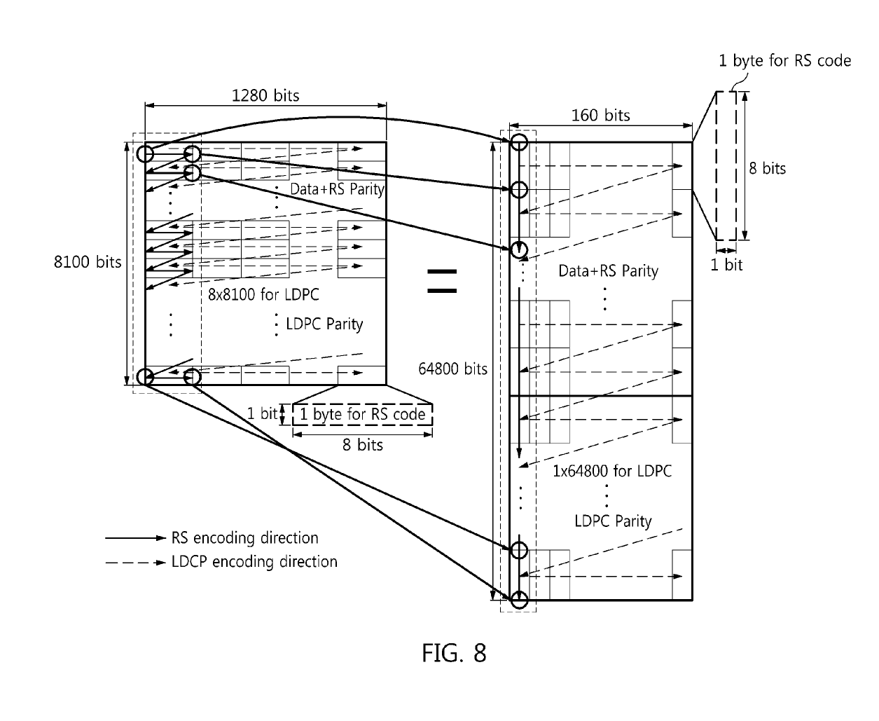

FIG. 6 is a diagram illustrating an LDPC-RS two-dimensional code in a form where information for RS encoding is arranged in a row direction, FIG. 7 is a diagram illustrating an LDPC-RS two-dimensional code in a form where information for RS encoding is arranged in a column direction, and FIG. 8 is a diagram illustrating that the LDPC-RS two-dimensional codes of FIGS. 6 and 7 are of the same type from a two-dimensional code viewpoint. A case where the code rate of an LDPC code is 1/4, the length thereof is 64800 bits and the length of an RS code is 160 bytes (1280 bits) is described as an example below.

The RS code is used to encode information on a byte basis. Accordingly, the LDPC-RS two-dimensional code may have a form in which input bytes (8 bits) for RS encoding are arranged in a row direction and a form in which input bytes for RS encoding are arranged in a column direction, as illustrated in FIGS. 6 and 7, respectively. Referring to FIG. 8, it can be seen that the above-described two LDPC-RS two-dimensional codes are each composed of 8100 RS codewords and 160 LDPC codewords and are exactly of the same type from a two-dimensional code viewpoint.

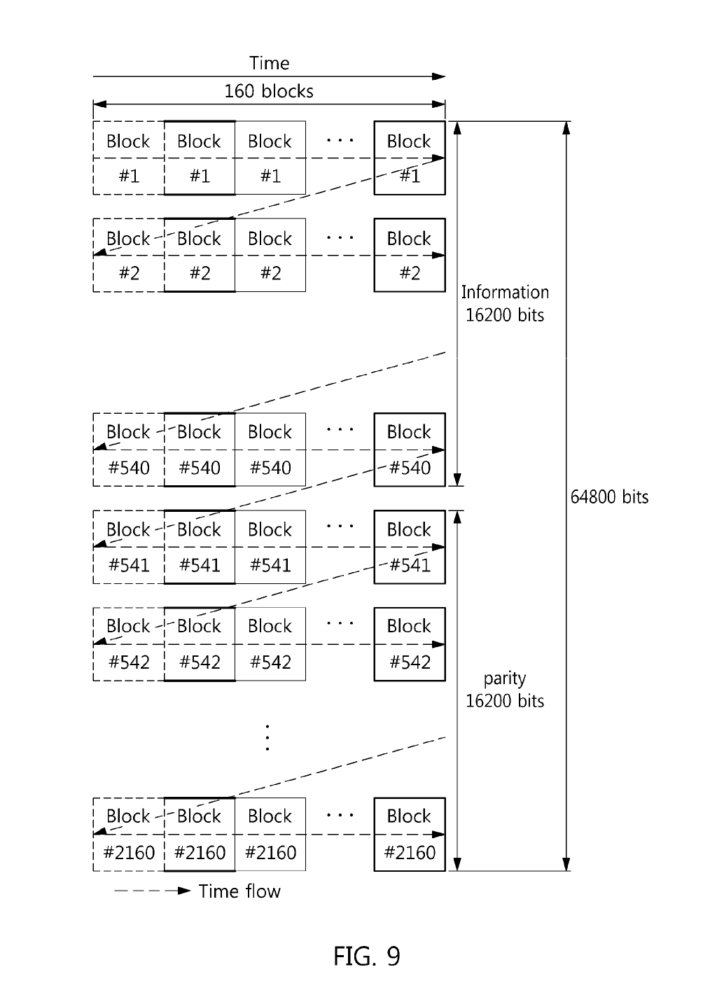

FIG. 9 is a diagram illustrating the partial decoding of an LDPC-RS two-dimensional code according to an embodiment of the present invention.

Since the LDPC code used in the LDPC-RS two-dimensional code has the same code rate-compatible characteristic as a raptor code, the code rate thereof may be varied by puncturing or truncating. In other words, the LDPC code can be successfully decoded using only the information and partial parity of the LDPC codeword. Accordingly, in an area where the signal to noise ratio (SNR) is relatively good, decoding using the partial information and parity of an LDPC codeword, that is, partial decoding, instead of decoding using a whole LDPC codeword, that is, full decoding, can be performed, and thus complexity and latency can be considerably decreased. In this case, the complexity refers to the amount of computation required for decoding, and the latency refers to the time for which a decoder should wait before the start of decoding. The partial decoding of an LDPC-RS two-dimensional code according to an embodiment of the present invention is described in detail with reference to FIG. 9.

An LDPC codeword that constitutes part of an LDPC-RS two-dimensional codeword may be divided into a plurality of blocks, as illustrated in FIG. 9. The LDPC code used in the LDPC-RS two-dimensional code has the above-described QC structure and is composed of CPMs having a size of L, and the size of the blocks may be determined to be a multiple of L. As an example, FIG. 9 illustrates a case where an LDPC codeword having a length of 64800 bits is divided into 2160 blocks having a length of 30 bits (the size of the CPMs). The blocks of the LDPC codeword may be sequentially transmitted in a row direction, as illustrated in FIG. 9. That is, the blocks may be output row by row in order to achieve a time and frequency interleaving effect.

When an LDPC codeword arranged in a column direction is divided into a plurality of blocks and then transmitted in a row direction as described above, fast decoding having low complexity and latency can be performed due to not only a time and frequency interleaving effect attributable to a block interleaver for an LDPC-RS two-dimensional code but also the code rate-compatible characteristic of the LDPC code.

For example, if it is assumed that a reception apparatus has received, among all the 2160 blocks (540 information blocks+1620 parity blocks) of an LDPC codeword, 780 blocks (540 information blocks+240 parity blocks), 1080 blocks (540 information blocks and 540 parity blocks), 1300 blocks (540 information blocks and 760 parity blocks) and 1620 blocks (540 information blocks and 1080 parity blocks), the code rates and lengths of the received LDPC codeword are as follows: 2/3-code rate 23400 bits (16200 information bits+7200 parity bits), 1/2-code rate 32400 bits (16200 information bits+16200 parity bits), 2/5-code rate 39000 bits (16200 information bits+22800 parity bits), and 1/3-code rate 48600 bits (16200 information bits+32400 parity bits). That is, if some of all the 2160 blocks of the LDPC codeword are received and then are subjected to partial decoding, this can considerably reduce complexity and latency compared to the conventional full decoding of an LDPC code having a 1/4 code rate and a 64800-bit length.

The following Table 2 lists the code rates, lengths, the numbers of “1” s in PCMs, the amounts of reduced complexity (each proportional to the number of “1” s in a PCM), and the amount of reduced latency of a 1/4-code rate LDPC mother code and punctured or truncated LDPC codes.

TABLE 2

| | | | Amount of | Amount of |
|---|---|---|---|---|
| Code | Length | Number of “1”s | reduced | reduced |
| rate | N | in PCM | complexity | latency |
| 1/4 | 64800 | 277,170 | — | — |
| 1/3 | 48600 | 199,260 | 28% | 25.0% |
| 2/5 | 39000 | 160,260 | 42% | 37.5% |
| 1/2 | 32400 | 121,190 | 56% | 50.0% |
| 2/3 | 23400 | 82,590 | 70% | 62.5% |

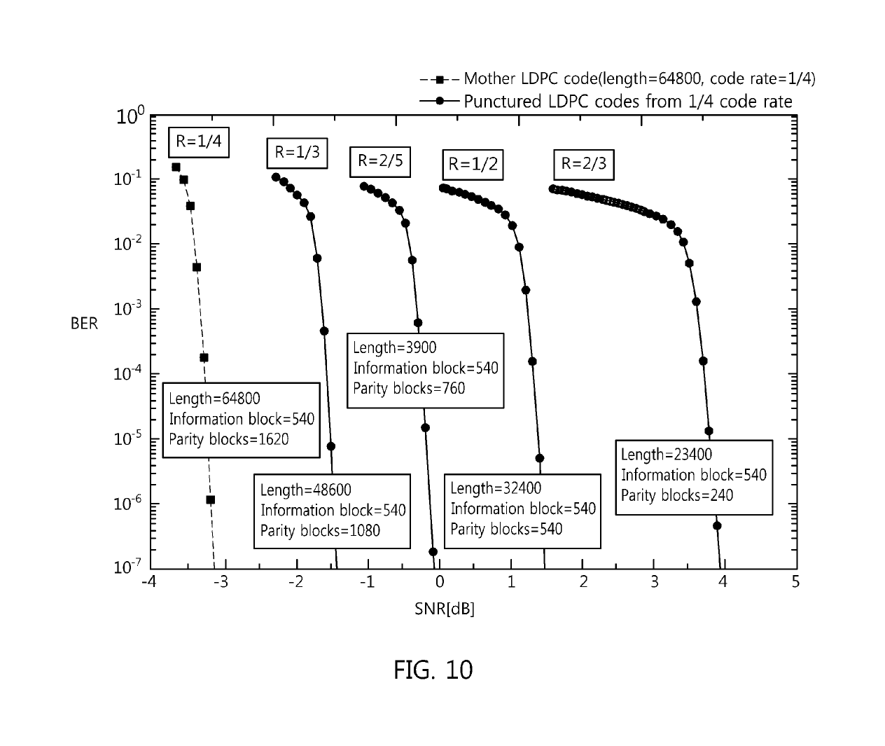

FIG. 10 is a graph illustrating performance based on the complexity and latency of an LDPC-RS two-dimensional code applied to an embodiment of the present invention. FIG. 10 illustrates the BER performance of an LDPC codeword having a length of 64800 bits and a code rate of 1/4 based on the length of received data in an AWGN channel against SNR as an example.

As illustrated in FIG. 10, if it is assumed that a reception apparatus has received 780 blocks (540 information blocks+240 parity blocks) among all the 2160 blocks (540 information blocks+1620 parity blocks) of an LDPC codeword, this corresponds to an LDPC code having a length of 23400 bits and a code rate of 2/3, and a performance of BER=10⁻⁶ is exhibited when the SNR is close to 4.5 dB.

Next, if it is assumed that a reception apparatus has received 1080 blocks (540 information blocks and 540 parity blocks) among all the 2160 blocks of an LDPC codeword, this corresponds to an LDPC code having a length of 32400 bits and a code rate of 2/3, and a performance of BER=10⁻⁶ is exhibited when the SNR is close to 2 dB.

In the same manner, if it is assumed that a reception apparatus has received 1300 blocks (540 information blocks and 760 parity blocks) among all the 2160 blocks of an LDPC codeword, this corresponds to an LDPC code having a length of 39000 bits and a code rate of 2/5, and a performance of BER=10⁻⁶ is exhibited when the SNR is close to 0 dB.

Furthermore, if it is assumed that a reception apparatus has received 1620 blocks (540 information blocks and 10800 parity blocks) among all the 2160 blocks of an LDPC codeword, this corresponds to an LDPC code having a length of 48600 bits and a code rate of 1/3, and a performance of BER=10⁻⁶ is exhibited when the SNR is close to −1.5 dB.

Finally, if it is assumed that a reception apparatus has received all the 2160 blocks of an LDPC codeword, this corresponds to a mother LDPC code having a length of 64800 bits and a code rate of 1/4, and a performance of BER=10⁻⁶ is exhibited when the SNR is close to −3 dB.

As described above, the LDPC code of the LDPC-RS two-dimensional code applied to an embodiment of the present invention exhibits varying performance based on the length of received data, and exhibits excellent performance in proportion to the length of a received codeword. In other words, performance is improved in proportion to reception complexity and latency.

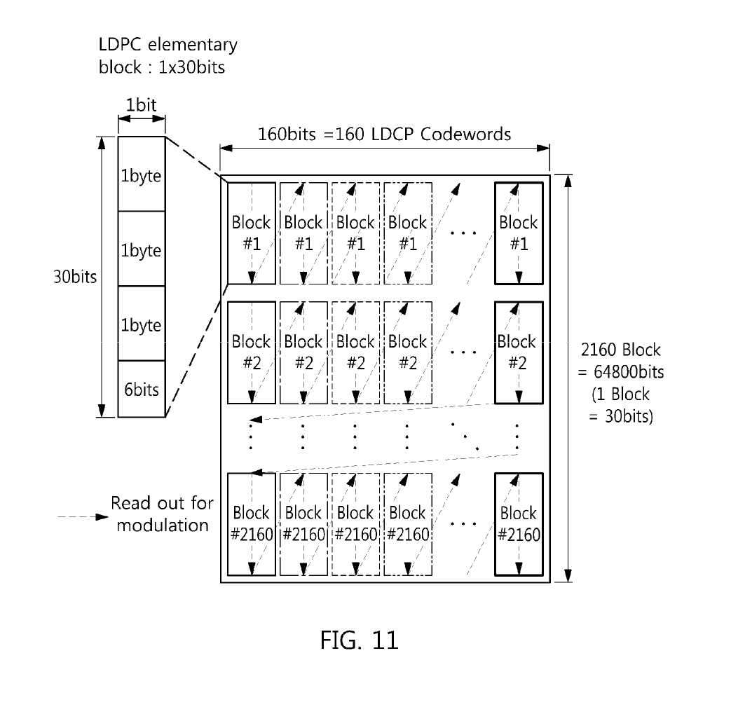

FIGS. 11 and 12 are diagrams illustrating information transmission methods using an LDPC-RS two-dimensional code according to embodiments of the present invention.

First, FIG. 11 illustrates a method of sequentially transmitting blocks ranging up to last 160 No. 2160 blocks in such a way as to sequentially transmit the 160 No. 1 blocks of the elementary blocks of an LDPC codeword, subsequently transmit 160 No. 2 blocks, and so forth. In contrast, FIG. 12 illustrates a method of transmitting the first bits of 160 No. 1 blocks, that is, 160 bits, subsequently transmitting the second 160 bits of No. 1 blocks, . . . , and finally transmitting the 30th 160 bits of last No. 2160 blocks. A bit-based transmission method, such as that of FIG. 12, provides an additional bit interleaving effect compared to a block-based transmission method, such as that of FIG. 11. However, in this case, a reception apparatus should wait for 4800 bits in order to receive a single block (30 bits), that is, an elementary block of an LDPC codeword, and thus a longer delay occurs during the decoding of an LDPC code.

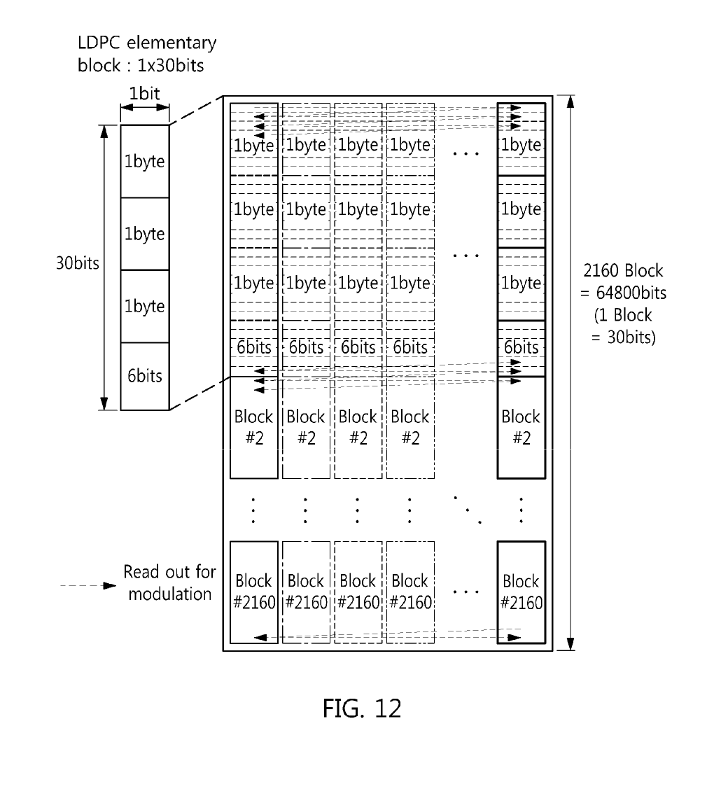

FIG. 13 is a flowchart illustrating a method of transmitting a terrestrial cloud transmission signal according to an embodiment of the present invention.

Referring to FIG. 13, a terrestrial cloud transmission signal transmission apparatus according to an embodiment of the present invention may encode information (input data) to be transmitted into a two-dimensional code including an LDPC code and an RS code at step 1310. As an example, the transmission apparatus may primarily encode the information to be transmitted using the RS code row by row, and may secondarily encode the formation using the LDPC code column by column. The two-dimensional code may be a code whose rows correspond to the RS code and whose columns correspond to the LDPC code. Furthermore, the LDPC code may be an LDPC code having a QC structure.

Thereafter, in order to effectively distribute burst errors occurring over a fading channel, the encoded information (an LDPC-RS codeword) may be output row by row at step 1320. In this case, the transmission apparatus may divide encoded information, which is encoded into the two-dimensional code, into a plurality of blocks based on the size of a PCM constituting the LDPC code, and may output the information divided into the plurality of blocks on a block or bit basis. This enables decoding to be performed faster than the case of bit-based output. In the case of block-based output, an additional bit interleaving effect is achieved.

The encoded information which is encoded into the LDPC-RS two-dimensional code according to an embodiment of the present invention may be successfully decoded by partial decoding using information and partial parity constituting the LDPC codeword when the SNR of the received signal is equal to or higher than a first threshold. In this case, RS decoding is not performed. Furthermore, the encoded information which is encoded into the LDPC-RS two-dimensional code according to an embodiment of the present invention may be decoded only by RS decoding, exclusive of LDPC decoding, without an error when the SNR of the received signal is equal to or higher than a second threshold.

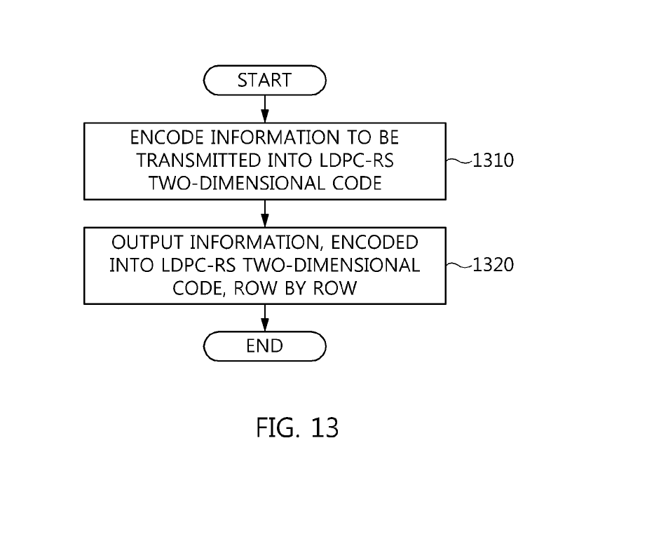

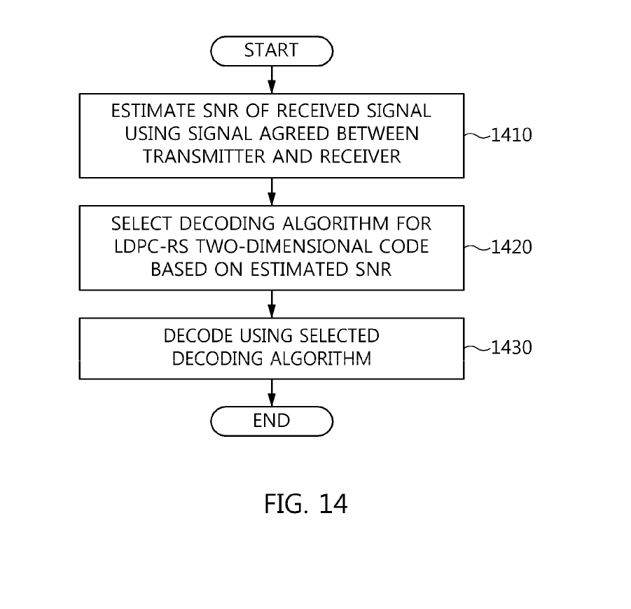

FIG. 14 is a flowchart illustrating a method of adaptively encoding an LDPC-RS two-dimensional code according to an embodiment of the present invention, and FIG. 15 is a diagram illustrating a case where only RS decoding is performed on an LDPC-RS two-dimensional code applied to an embodiment of the present invention.

A reception apparatus for receiving an LDPC-RS two-dimensional code according to an embodiment of the present invention estimates the SNR of a received signal using a signal agreed between a transmitter and a receiver in order to adaptively decode an LDPC-RS two-dimensional codeword at step 1410. In this case, the agreed signal may be a preamble signal, a pilot signal, a training signal, or the like.

Thereafter, the reception apparatus determines a decoding algorithm to be applied to an LDPC-RS two-dimensional codeword, encoded in an LDPC-RS two-dimensional code including an LDPC code and an RS code, based on the estimated SNR at step 1420. In this case, the LDPC-RS two-dimensional codeword may be a codeword that has been primarily encoded using an RS code row by row and secondarily encoded using an LDPC code column by column.

More specifically, the reception apparatus may determine at least one of an LDPC decoding algorithm and an RS decoding algorithm to be the decoding algorithm to be applied to the LDPC-RS two-dimensional codeword. In this case, if it is determined that the LDPC decoding algorithm will be applied to the codeword, the reception apparatus determines any one of an LDPC decoding algorithm (full decoding algorithm) using the whole LDPC-RS two-dimensional codeword and an LDPC decoding algorithm (a partial decoding algorithm) using part of the LDPC-RS two-dimensional codeword (an information portion and part of LDPC parity) to be an LDPC decoding algorithm to be applied to the LDPC-RS two-dimensional codeword and then decodes the LDPC-RS two-dimensional codeword using the determined decoding algorithm at step 1430.

For example, the reception apparatus may apply LDPC-RS decoding methods based on SNR values, as illustrated in the following Table 3:

TABLE 3

| | | Secondary RS |
|---|---|---|
| SNR value | Primary LDPC decoding | decoding |
| reception SNR < threshold + 0.5 dB | full decoding | RS decoding |
| | (decoding using 2160 blocks) | |
| threshold + 0.5 dB ≦ reception SNR < | full decoding | omitted |
| threshold + 2.5 dB | (decoding using 2160 blocks) | |
| threshold + 2.5 dB ≦ reception SNR < | partial decoding | omitted |
| threshold + 4.0 dB | (decoding using 1620 blocks) | |
| threshold + 4.0 dB ≦ reception SNR < | partial decoding | omitted |
| threshold + 5.5 dB | (decoding using 1300 blocks) | |
| threshold + 5.5 dB ≦ reception SNR < | partial decoding | omitted |
| threshold + 8.5 dB | (decoding using 1080 blocks) | |
| threshold + 8.5 dB ≦ reception SNR < | partial decoding | omitted |
| threshold + 23.5 dB | (decoding using 780 blocks) | |
| threshold + 23.5 dB ≦ reception SNR | omitted | RS decoding |

In this case, the threshold refers to the performance limit of the LDPC-RS two-dimensional code, and is −3.4 dB in an AWGN channel, as illustrated in FIG. 4. This means that information can be received without an error only if the reception SNR is equal to or higher than −3.4 dB.

The thresholds listed in Table 3 may vary depending on the length and code rate of the LDPC code and the length and error correction capability of the RS code. Furthermore, the thresholds may vary depending on intervals that divide the received SNR, that is, the definition of the number of LDPC blocks to be used based on the received SNR.

The LDPC-RS two-dimensional code according to an embodiment of the present invention can be successfully restored by RS decoding without LDPC decoding in a very-high SNR environment (in the case of reception near a transmitter). As an example, if the reception apparatus has received 160 No. 1 blocks, as illustrated in FIG. 15, it may be possible to restore three RS codewords of 3.75 RS codewords. Accordingly, the reception apparatus may restore information with minimum complexity and latency by performing only RS decoding without LDPC decoding in a high-SNR environment (for example, an area near a transmitter).

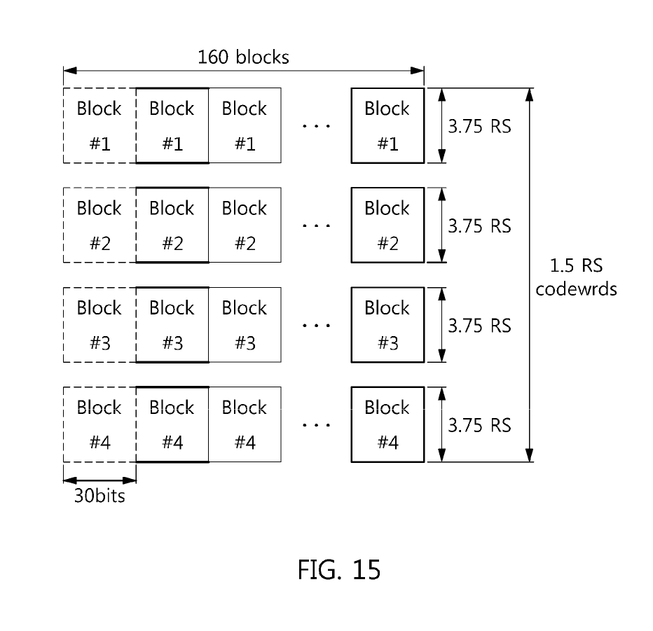

FIG. 16 is a block diagram illustrating a transmission apparatus for transmitting a codeword encoded in an LDPC-RS two-dimensional code according to an embodiment of the present invention.

Referring to FIG. 16, a transmission apparatus 1600 for transmitting a terrestrial cloud transmission signal according to the present embodiment may include an encoding unit 1610, and an output unit 1620.

The encoding unit 1610 encodes information to be transmitted into a two-dimensional code including an LDPC code and an RS code. The two-dimensional code may be a code whose rows correspond to the RS code and whose columns correspond to the LDPC code, and the LDPC code may be a QC-LDPC code. As an example, the encoding unit 1610 may primarily encode the information to be transmitted using the RS code row by row, and may secondarily encode the information using the LDPC code column by column. Furthermore, the encoded information may be divided into a plurality of blocks based on the size of a PCM that constitutes the LDPC code.

The output unit 1620 outputs the information encoded by the encoding unit 1610 row by row. The output unit 1620 may output the information divided into the plurality of blocks on a block or bit basis.

The encoded information which is encoded into the LDPC-RS two-dimensional code by the transmission apparatus 1600 may be successfully restored by partial decoding using information and partial parity that constitute the LDPC codeword when the SNR of a received signal is equal to or higher than a first threshold. Furthermore, the information may be successfully restored only by RS decoding without LDPC decoding when the SNR of a received signal is equal to or higher than a second threshold. Moreover, the information may be successfully restored by full decoding in an area where the SNR of the received signal is low (in the periphery of a broadcasting service zone).

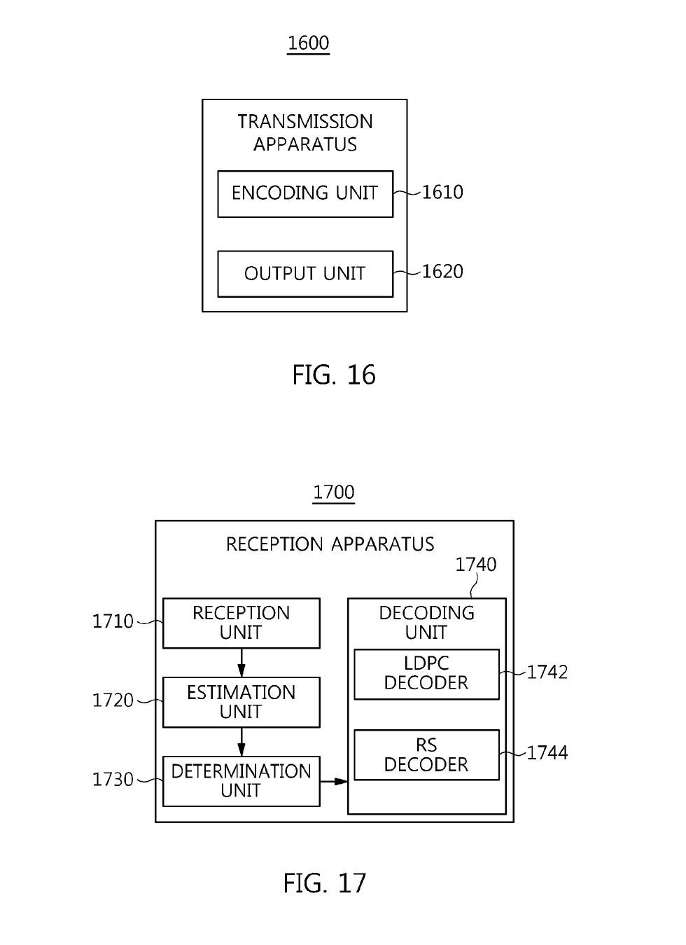

FIG. 17 is a block diagram illustrating a reception apparatus for receiving a codeword encoded in an LDPC-RS two-dimensional code according an embodiment of the present invention.

Referring to FIG. 17, a reception apparatus 1700 for receiving an LDPC-RS two-dimensional code according to the present embodiment may include a reception unit 1710, an estimation unit 1720, a determination unit 1730, and a decoding unit 1740.

The reception unit 1710 receives an LDPC-RS two-dimensional codeword, a signal agreed between a transmitter and a receiver, etc. from the transmitter.

The estimation unit 1720 estimates the SNR of the received signal. As an example, the estimation unit 1720 may estimate the SNR of the received signal based on any one of a preamble signal, a pilot signal and a training signal.

The determination unit 1730 determines a decoding algorithm to be applied to the codeword, encoded in a two-dimensional code (an LDPC-RS two-dimensional code) including an LDPC code and an RS code, based on the SNR estimated by the estimation unit 1720. In this case, the LDPC-RS two-dimensional code may be a code whose rows correspond to the RS code and whose columns correspond to the LDPC code. Alternatively, the LDPC-RS two-dimensional code may be a code whose rows correspond to the LDPC code and whose columns correspond to the RS code. In this case, the LDPC code may be an LDPC code having a QC structure, and part of the parity thereof may include an identity matrix. The codeword encoded in the LDPC-RS two-dimensional code may be a codeword that has been primarily encoded using the RS code row by row and secondarily encoded using the LDPC code column by column.

As an example, the determination unit 1730 may determine at least one of an LDPC decoding algorithm and an RS decoding algorithm to be a decoding algorithm to be applied to the LDPC-RS two-dimensional codeword based on the SNR estimated by the estimation unit 1720, as shown in Table 3. If it is determined that the LDPC decoding algorithm will be applied to the LDPC-RS two-dimensional codeword, the determination unit 1730 may determine any one of an LDPC decoding algorithm (a full decoding algorithm) using the whole codeword and an LDPC decoding algorithm (a partial decoding algorithm) using part of the codeword to be an LDPC decoding algorithm to be applied to the codeword.

The decoding unit 1740 decodes the LDPC-RS two-dimensional codeword using the decoding algorithm determined by the determination unit 1730. For this purpose, the decoding unit 1740 may include an LDPC decoder 1742, and an RS decoder 1744.

Meanwhile, although a case where the determination unit 1730 is included in the reception apparatus 1700 has been illustrated in FIG. 17, the determination unit 1730 may be included in the decoding unit 1740 as desired. In this case, when information about the SNR and the LDPC-RS two-dimensional codeword are input, the decoding unit 1740 itself may adaptively decode the LDPC-RS two-dimensional codeword based on the SNR. In this case, the decoding unit 1740 may be implemented as an independent decoding device, and the decoding device may include a determination unit configured to determine a decoding algorithm to be applied to the codeword encoded in the two-dimensional code including the LDPC code and the RS code based on the estimated SNR of the received signal and a decoding unit configured to decode the codeword using the determined decoding algorithm.

The foregoing description has been provided merely to illustrate the technical spirit of the present invention, and those having ordinary knowledge in the art to which the present invention pertains may make various modifications and variations within a range that does not depart from the essential characteristics of the present invention. Accordingly, the embodiments disclosed herein are not intended to limit the technical spirit of the present invention, but are intended to illustrate the technical spirit of the present invention, and thus the scope of the technical spirit of the present invention is not limited by the embodiments. The range of protection of the present invention should be interpreted based only on the attached claims, and all technical concepts falling within a range equivalent to the technical spirit of the present invention should be construed as falling within the range of rights of the present invention.

1. A method of transmitting a terrestrial cloud transmission signal, comprising:
encoding information to be transmitted into a two-dimensional code including a low density parity check (LDPC) code and a Reed Solomon (RS) code; and
outputting encoded information, which is encoded into the two-dimensional code, row by row.

2. The method of claim 1, wherein the two-dimensional code is a code whose rows correspond to the RS code and whose columns correspond to the LDPC code.

3. The method of claim 1, wherein the LDPC code is an LDPC code having a Quasi-Cyclic (QC) structure.

4. The method of claim 1, wherein:
the LDPC code comprises matrix A having a size of g×K, a matrix B having a size of g×g, matrix C having a size of (N−K−g)×(K+g), matrix D having a size of (N−K−g)×(N−K−g), and matrix Z having a size of g×(N−K−g); and
N is a length of a codeword, K is a length of information, and g is a value varying depending on a code rate.

5. The method of claim 1, wherein encoding the information comprises primarily encoding the information to be transmitted using the RS code row by row and secondarily encoding the information using the LDPC code column by column.

6. The method of claim 1, further comprising, after encoding the information, dividing the encoded information, which is encoded into the two-dimensional code, into a plurality of blocks based on a size of a cyclic permutation matrix (CPM) constituting the LDPC code.

7. The method of claim 6, wherein outputting the encoded information comprises outputting divided information, which is divided into the plurality of blocks, in a unit of a block.

8. The method of claim 6, wherein outputting the encoded information comprises outputting divided information, which is divided into the plurality of blocks, in a unit of a bit.

9. The method of claim 1, wherein the encoded information which is encoded into the two-dimensional code is restored by partial decoding using information and partial parity constituting an LDPC codeword if a signal to noise ratio (SNR) of a received signal is equal to or higher than a first threshold.

10. The method of claim 1, wherein the encoded information which is encoded into the two-dimensional code is restored only by RS decoding without LDPC decoding if an SNR of a received signal is equal to or higher than a second threshold.

11. A method of decoding a codeword encoded in a two-dimensional code including a low density parity check (LDPC) code and a Reed Solomon (RS) code, comprising:
estimating an SNR of a received signal;
determining a decoding algorithm to be applied to a codeword based on the estimated SNR; and
decoding the codeword using the determined decoding algorithm.

12. The method of claim 11, wherein the two-dimensional code is a code whose rows correspond to the RS code and whose columns correspond to the LDPC code or a code whose rows correspond to the LDPC code and whose columns correspond to the RS code.

13. The method of claim 11, wherein the LDPC code is an LDPC code having a Quasi-Cyclic (QC) structure in which part of parity includes an identity matrix.

14. The method of claim 11, wherein the codeword is a codeword that has been primarily encoded using the RS code row by row and secondarily encoded using the LDPC code column by column.

15. The method of claim 11, wherein estimating the SNR comprises estimating the SNR using any one of a preamble signal, a pilot signal and a training signal.

16. The method of claim 11, wherein determining the decoding algorithm comprises determining at least one of an LDPC decoding algorithm and an RS decoding algorithm to be the decoding algorithm to be applied to the codeword.

17. The method of claim 16, wherein determining the decoding algorithm further comprises, if it is determined that the LDPC decoding algorithm will be applied to the codeword, determining any one of an LDPC decoding algorithm using the whole codeword and an LDPC decoding algorithm using part of the codeword to be the LDPC decoding algorithm to be applied to the codeword.

18. A decoding device, comprising:
a determination unit configured to determine a decoding algorithm to be applied to a codeword, encoded in a two-dimensional code including a low density parity check (LDPC) code and a Reed Solomon (RS) code, based on an estimated SNR of a received signal; and
a decoding unit configured to decode the codeword using the determined decoding algorithm.

19. The decoding device of claim 18, wherein the codeword is a codeword that has been primarily encoded using the RS code row by row and secondarily encoded using the LDPC code column by column.

20. The decoding device of claim 18, wherein the determination unit determines at least one of an LDPC decoding algorithm and an RS decoding algorithm to be the decoding algorithm to be applied to the codeword, and, if it is determined that the LDPC decoding algorithm will be applied to the codeword, determines any one of an LDPC decoding algorithm using the whole codeword and an LDPC decoding algorithm using part of the codeword to be the LDPC decoding algorithm to be applied to the codeword.
